(19) United States
(12) Patent Application Publication
(10) Pub. No.: US 2011/0169488 A1
(43) Pub. Date: Jul. 14, 2011

(54) METHOD AND STRUCTURE FOR TESTING AND CALIBRATING MAGNETIC FIELD SENSING DEVICE

(75) Inventor: Phillip Mather, Maricopa, AZ (US)

(73) Assignee: EVERSPIN TECHNOLOGIES, INC., Chandler, AZ (US)

(21) Appl. No.: 12/684,692

(22) Filed: Jan. 8, 2010

(51) Int. Cl. G01R 33/02

(52) U.S. Cl. 324/252

(57) ABSTRACT

A method of sensing a magnetic field including at least one magnetoresistive sensing element (100) in a circuit (101) includes supplying (702) a first plurality of currents to a stabilization line (116) disposed adjacent the magnetoresistive sensing element (100), applying (704) a second plurality of currents to a self test line (120) disposed adjacent the magnetic tunnel junction (100), one each of the first plurality of currents being supplied during one each of the second plurality of currents. Values sensed by the magnetic tunnel junction sensing element (100) in response to the supplying (702) of the first plurality of currents and the applying (704) of the second plurality of currents are sampled (706) and the sensitivity of the magnetic tunnel junction sensor (100) and electrical and magnetic offset are determined (708) from the sampled values. The temperature coefficient of offset may also be determined.

### FIELD OF THE INVENTION

The present invention generally relates to a magnetic field sensing device and more particularly to a magnetic tunnel junction field sensor providing on-chip testing and calibration.

### BACKGROUND OF THE INVENTION

Sensors are widely used in modern systems to measure or detect physical parameters, such as direction, position, motion, force, acceleration, and temperature, pressure. While a variety of different sensor types exist for measuring these and other parameters, they all suffer from various limitations. For example, inexpensive low field sensors, such as those used in an electronic compass and other similar magnetic sensing applications, generally comprise anisotropic magnetoresistance (AMR) based devices. In order to arrive at the required sensitivity and reasonable resistances that mesh well with CMOS, the chip area of such sensors are generally in the order of square millimeters in size. Furthermore, large set-reset pulses from bulky coils of approximately 500 mA are typically required. For mobile applications, such AMR sensor configurations are costly, in terms of expense, circuit area, and power consumption.

Other types of sensors, such as magnetic tunnel junction (MTJ) sensors, giant magnetoresistance (GMR) sensors, and Hall effect sensors have been used to provide smaller profile sensors, but such sensors have their own concerns, such as inadequate sensitivity and the temperature dependence of their magnetic field response. To address these concerns, MTJ, GMR, and AMR sensors have been employed in a Wheatstone bridge structure to increase sensitivity and to reduce the temperature dependent resistance changes. Only recently have Hall effect sensors become competitive in this type of application through the development of high sensitivity Si based sensors coupled with a thick NiFe magneto-concentrator for amplification of the local magnetic field. These hall effect devices typically employ the current spinning technique for optimal temperature response, resulting in a larger than desired CMOS footprint for the circuitry associated with the multiplexing between the various tap point functionality. For minimal sensor size and cost, MTJ elements are preferred.

As a result of the manufacturing process variations, low field Wheatstone bridge based magnetic sensors may exhibit a small yet variable residual offset. Temperature shifts, mechanical stress, and the aging of the device may cause small changes in this offset. Furthermore, conventional magnetic sensors have a sensitivity built into the device by factors such as sense layer thickness, shape, and flux concentrator geometry. Therefore, small variations in the manufacturing process may create variations in the sensor parameters and therefore create a need for the magnetic sensors be tested and calibrated for optimal performance.

As magnetic sensor size becomes smaller, the packaging and test costs begin to dominate the final product cost. For a magnetic field sensing solution that minimizes manufacturing costs, increasingly attention must be paid to minimization of test time and complexity. Additionally, as packaging and final test are increasingly performed by contractors at remote locations with massively parallel testing systems, the large development and installation cost of specialized test apparatus to apply an external magnetic field for testing of sensor characteristics becomes prohibitive. An additional problem is that the magnetic environment may not be completely controlled on the production floor.

Accordingly, it is desirable to provide an inexpensive low field sensor and method that provides on chip testing and calibration. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

The magnetic field sensor includes first and second current carrying lines, a stabilization line, a first magnetic tunnel junction sensing element positioned between the first and second current carrying lines and adjacent to the stabilization line, and a magnetic field generating line positioned adjacent the first magnetic tunnel junction sensing element.

A method of sensing a magnetic field including at least one magnetic tunnel junction sensing element in an integrated circuit includes supplying a first plurality of currents to a stabilization line disposed adjacent the magnetic tunnel junction, applying a second plurality of currents to a self test line disposed adjacent the magnetic tunnel junction, one each of the first plurality of currents being supplied during one each of the second plurality of currents, sampling values sensed by the magnetic tunnel junction sensing element in response to the supplying of the first and second plurality of currents; and determining the sensitivity, magnetic offset, and electrical offset of the magnetic tunnel junction sensor from the sampled values.

### BRIEF DESCRIPTION OF THE DRAWINGS

The present invention will hereinafter be described in conjunction with the following drawing figures, wherein like numerals denote like elements, and

FIG. 1 is a cross section of a magnetic tunnel junction device in accordance with a first exemplary embodiment;

FIG. 2 is a cross section of a magnetic tunnel junction device in accordance with a second exemplary embodiment;

FIG. 3 is a schematic diagram of a Wheatstone bridge including four of the magnetic tunnel junction devices of FIG. 1 or FIG. 2;

FIG. 4 is a graph of the magnetic tunnel sensor output versus a self test field for two different stabilization fields in the exemplary embodiment of FIG. 1 or FIG. 2;

FIG. 5 is a top schematic view of the exemplary embodiment of FIG. 1 or FIG. 2 with a self test line formed as a pancake coil;

FIG. 6 is a top schematic view of the exemplary embodiments of FIG. 1 or FIG. 2 with self test lines grouped in parallel;

FIG. 7 is a top schematic view of a self test line in relation to the magnetic tunnel junctions;

FIG. 8 is a flow chart of a first method for determining sensitivity factors and electrical offset of the magnetic tunnel junction device in accordance with an exemplary embodiment; and

FIG. 9 is a flow chart of a second method for determining sensitivity factors and electrical offset of the magnetic tunnel junction device in accordance with an exemplary embodiment.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

Small footprint magnetic sensors typically are laid out in a Wheatstone bridge configuration, where a precise balance between the resistances of the circuit elements must be maintained for the bridge to produce a minimal response in a zero magnetic field. Any nonzero response (bridge offset) present from the manufacturing process must be calibrated or nulled out to produce signals that are free from error. These offsets may shift over the lifetime of the part, in response to temperature changes, mechanical stresses, or other effects. In a compass application with a typical field response of 1.0 to 5.0 mV/V/Oe, maintaining an accuracy of less than one degree implies that shifts in offset of less than 10 μV must be removed or calibrated out of the error signal. This calibration is accomplished as described herein by the inclusion of an additional self test line routed in an upper metal layer that is also used as the aluminum termination of the copper pads. In this manner, additional functionality is added to the sensor with minimal or no additional manufacturing cost. While line resistances are not crucial for implementation at final test, the ability to offer a self test mode in a final portable application requires resistances low enough that the supply voltages can source sufficient current to create the self test field. The additional desire for low power consumption creates a need for the lowest source current possible, as the application specific integrated circuit (ASIC) supplying the current will need to draw from the voltage Vdd. The current paths that the self test routing takes can be wired with various widths and various segments connected together in series or parallel. This does not change the overall current flowing above each individual sense element, but does impact the total current that must be sourced. As a low supply current to the self test line is targeted, care should be taken to create the largest number of lines wired in series for which the source voltage will provide sufficient self test field. For a 2.0 um line width (sufficient to cover the sensors under measurement), all lines passing over active sensors may be wired in series and a self test field of 8.0 Oe can be applied at Vdd=2.0V with 6.5 mA.

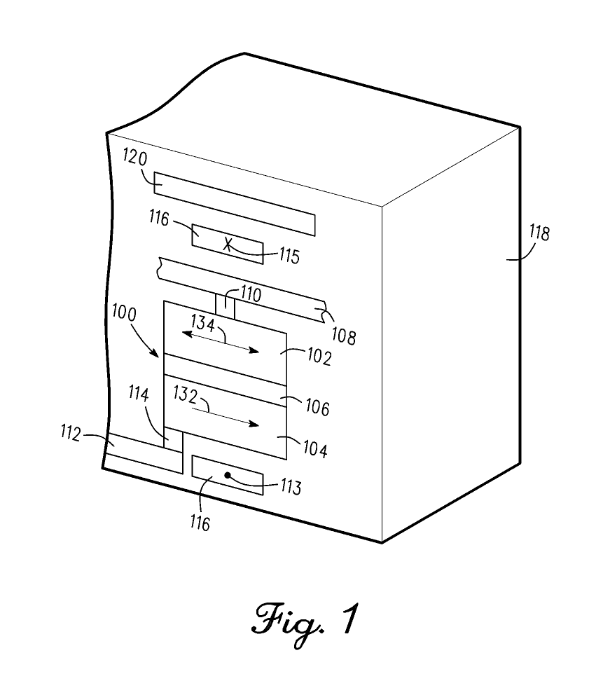

Referring to FIG. 1, the exemplary magnetic field sensing device 101 includes a magnetic tunnel device 100 formed within a dielectric material 118 and includes a ferromagnetic sense layer 102 and a fixed ferromagnetic region 104 separated by a tunnel barrier 106. The sense layer 102 is coupled to a first conductive line 108 by a via 110, and the fixed region 104 is coupled to a second conductive line 112 by a via 114. A stabilization line (current carrying line) 116 is positioned on opposed sides of the magnetic tunnel device 100 near both the sensor layer 102 and the fixed region 104. The direction of the current 115 is represented by the “X” 115 as going into the page and by the “dot” 113 as coming from the page, though the direction could be reversed. Although the stabilization line 116 is shown to be near both the sense layer 102 and the fixed region 104 in accordance with the preferred embodiment, it should be understood that it may be positioned on only one side of the magnetic tunnel device 100 near either the sense layer 102 or the fixed region 104.

The fixed magnetic region 104 is well known in the art, and conventionally includes a fixed layer (not shown) disposed between the tunnel barrier and an anti-ferromagnetic coupling spacer layer (not shown). The anti-ferromagnetic coupling spacer layer is formed from any suitable nonmagnetic material, for example, at least one of the elements Ru, Os, Re, Cr, Rh, Cu, or their combinations. A pinned layer (not shown) is disposed between the anti-ferromagnetic coupling spacer layer and an optional pinning layer. The sense layer 102 and the fixed layer may be formed from any suitable ferromagnetic material, such as at least one of the elements Ni, Fe, Co, B, or their alloys as well as so-called half-metallic ferromagnets such as NiMnSb, PtMnSb, Fe₃O₄, or CrO₂. The tunnel barrier 106 may be insulator materials such as AlOx, MgOx, RuOx, HfOx, ZrOx, TiOx, or the nitrides and oxidinitrides of these elements.

The ferromagnetic fixed and pinned layers each have a magnetic moment vector that are usually held anti-parallel by the anti-ferromagnetic coupling spacer layer resulting in a resultant magnetic moment vector 132 that is not free to rotate and is used as a reference. The sense layer 102 has a magnetic moment vector 134 that is free to rotate in the presence of a magnetic field. In the absence of an applied field, magnetic moment vector 134 is oriented along the anisotropy easy-axis of the sense layer.

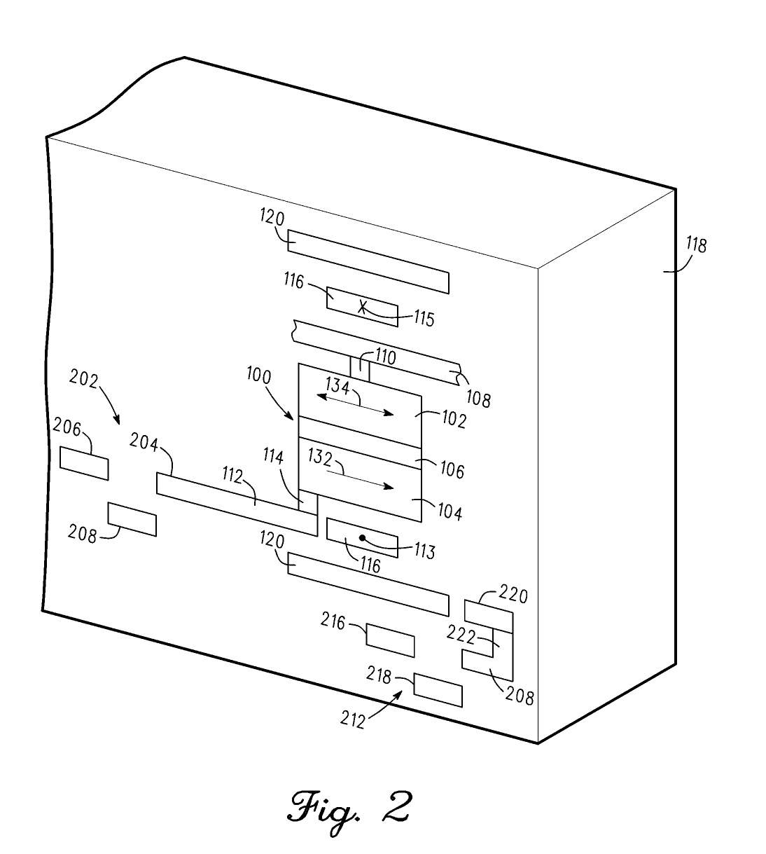

In accordance with an exemplary embodiment, a self test line 120 is deposited above the stabilization line 116 and separated therefrom by the dielectric material 118. The self test line 120 is a metal layer, preferably aluminum, that generates a magnetic field when a current is passed therethrough. The self test line 120 may be deposited when a contact pad (not shown) is deposited, thereby saving process steps. The contact pad typically is a termination metal, e.g., aluminum, of a copper pad (not shown). In another embodiment, the self test line 120 may be routed on two separate metal layers, in a similar fashion to the stabilization line 116, whereby current moves in opposing directions on the two different layers (FIG. 2).

In the exemplary embodiments of FIGS. 1 and 2, the dielectric material 118 may be silicon oxide, silicon nitride (SiN), silicon oxynitride (SiON), a polyimide, or combinations thereof. The conductive lines 108, 112, vias 110, 114, and stabilization line 116, are preferably copper, but it will be understood that they may be other materials such as tantalum, tantalum nitride, silver, gold, aluminum, platinum, or another suitable conductive material.

In both the exemplary embodiments of FIGS. 1 and 2, CMOS or bipolar circuitry may optionally be formed within the same integrated circuit. For example, referring to FIG. 2, a CMOS transistor 202 has a first current carrying electrode 204 and a second current carrying electrode 206 formed at the same layer as conductive line 112. The first current carrying electrode 204 is formed integrally with the conductive line 112, while the second current carrying electrode 206 is electrically isolated from the conductive line 112. The second current carrying electrode 206 may be coupled, for example, to a digital to analog converter (not shown) and a control electrode 208 would be coupled to control circuitry (not shown). Another example is the transistor 212 having a first current carrying electrode 214, a second current carrying electrode 216, and a control electrode 218. The second current carrying electrode 226 may for example be coupled to ground and the control electrode 218 to another control circuit (not shown). A contact pad 220 is formed in the same process layer as the self test line 120 and is coupled to the source 214 by a via 222. Such a configuration enables electrical contact between integral circuitry and the sense elements, self test and stabilization lines. The same metal layers used for bridge wiring and self test/stabilization currents may also be used for metal layers in adjacent circuitry. The circuitry may either underlay or sit adjacent to the sense elements. While only two transistors 202, 212 are shown for simplicity, a large plurality of transistors and other circuit elements would comprise the optional circuitry.

During fabrication of the magnetic tunnel device 100, each succeeding layer is deposited or otherwise formed in sequence and each magnetic tunnel device 100 may be defined by selective deposition, photolithography processing, etching, etc. using any of the techniques known in the semiconductor industry. During deposition of at least the fixed region 104, a magnetic field is provided to set a preferred anisotropy easy-axis (induced intrinsic anisotropy). The provided magnetic field creates a preferred anisotropy easy-axis for magnetic moment vectors 132. In addition to intrinsic anisotropy, sense elements having aspect ratios greater than one may have a shape anisotropy, and the combination of this shape and the intrinsic anisotropy define an easy axis that is preferably parallel to a long axis of the sense element. This easy axis may also be selected to be at about a 30 to 90 degree angle, with the reference magnetization 132. In the bridge embodiment with no flux concentrators, this is preferably at about a 45-degree angle.

Four of the magnetic tunnel sense elements 100 are combined to form a Wheatstone bridge 300 (FIG. 3). Each resistor represented in the magnetic tunnel devices 100 may be an array (not shown) of magnetic tunnel junction sense elements for improved reliability and signal/noise ratio. The direction of current flow through the sense elements is preserved in each of the legs, so from the voltage input 108 along either path of the bridge, the current flows either from the top to the bottom or the bottom to the top of the magnetic tunnel junction stack. The stabilization line 116 is positioned to provide current near each of the four magnetic tunnel devices 100. Though the stabilization line 116 may be disposed on only one side of the magnetic tunnel devices 100, it preferably is also disposed on the opposed side thereof, thereby doubling the effective field applied for a given current. For example, FIG. 1 depicts the current going into the page (represented by an X), and coming from the page (represented by a dot). FIG. 3 depicts the opposed current direction by the zigzag fashion of the stabilization 116 across each magnetic tunnel device 100. The bridge is supplied with a constant voltage bias between voltage source terminals 108 and 112. The sensor response is differentially measured across the midsection of the bridge at nodes, or outputs, 302 and 304. The self test line 120 is shown also routing over the sense elements in a dotted line to distinguish it from the stabilization line.

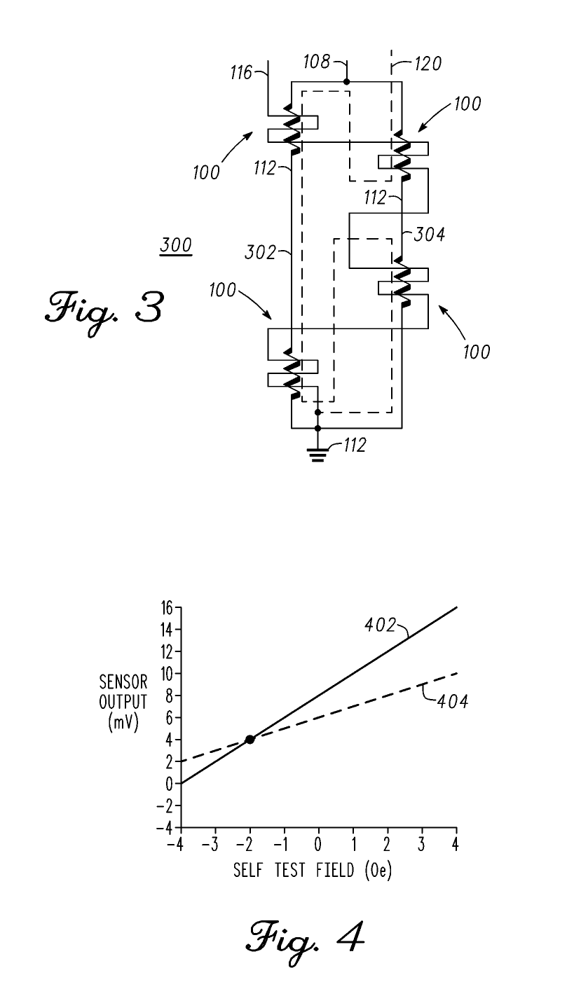

FIG. 4 shows a plot of the signal response of an exemplary sensor with an electrical offset of 4 mV/V and sensitivity of 2 mV/V at 2 mA of stabilization current, in a fixed field of 2 Oe, and in the presence of various self test fields. The two lines 402 (the sensor output at 2 mA of stabilization current) and 404 (the sensor output at 20 mA of stabilization current) intersect at the magnetic offset field (on the x axis) and the electrical offset (on the y axis). While the correlated double sampling described herein may be applied to various bridge orientations, one example may be found in U.S. patent application Ser. No. 12/055,482, assigned to the assignee of the present application.

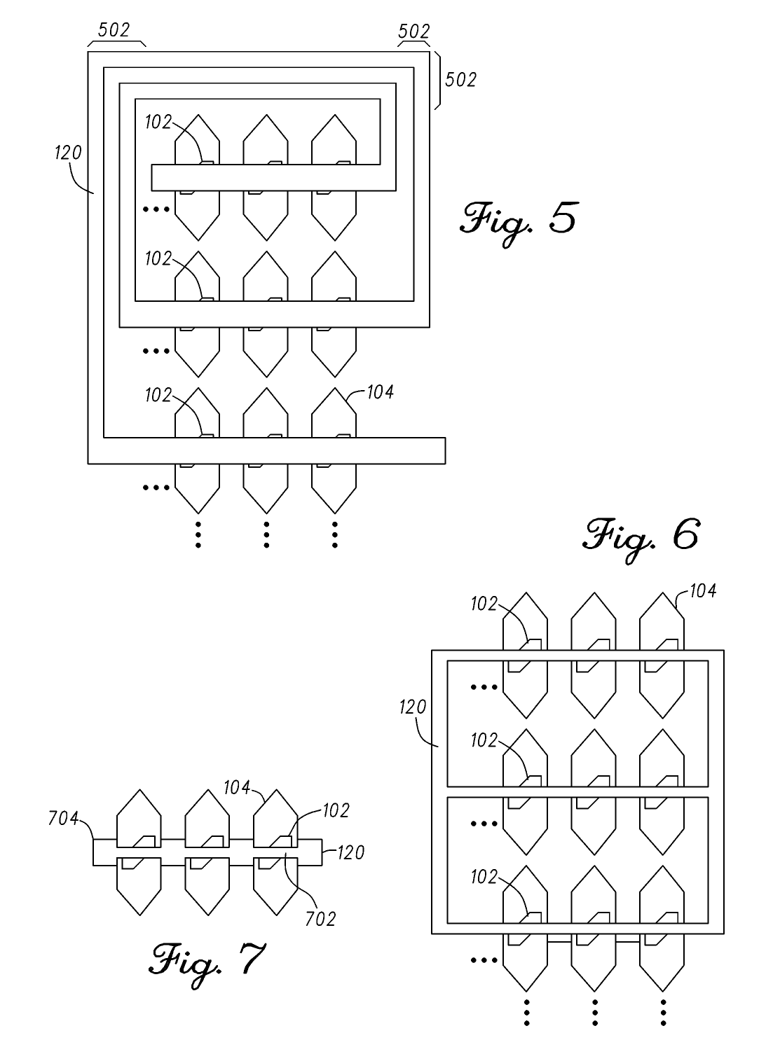

As very large currents (on the order of tens of mA) must be sourced to apply a field of a few Oe of self test field as additional segments are connected together in a parallel configuration, it is advantageous to determine at the outset what the maximum magnetic field that must be applied and design the largest possible line resistance for which that field can be applied at the lowest available bias voltage. Another large advantage to working at the highest possible line resistance is that pad sharing then becomes a possibility. The ground pad for a stabilization line (that produces the sensor stabilization field) may then also be used as ground for a self test line (that applies the self test field). For lower resistances, the ground pad must also sink the larger current required to apply a given field, and can cause the ground level to shift. This can then impact the apparent stabilization line resistance, and can result in a higher than expected voltage needed to drive the required stabilization current and self test current simultaneously. Ideally, the resistances and currents that must be sourced in the self test line 120 and stabilization current lines 116 are about the same to minimize the impacts of this problem. As die area is of crucial importance, and it is generally possible to save some die area for a “pancake” self test coil 120 (FIG. 5), whereby all self test line routing is contained within a single plane, and hence lower the sensor cost by connecting a plurality of adjacent runs 120 into groups (three are shown for simplicity) over the sense elements 102 in parallel (FIG. 6). FIG. 5 shows the die area that may be saved (denoted by brackets 502) in an example subsection of a sense array from connecting three adjacent runs. While it is desirable for field uniformity that the self test line 120 cover the entire sense element 102, in such a case, as shown in FIG. 5, the self test runs 120 wired in parallel (FIG. 6) may be somewhat reduced in width to partially compensate and keep the resistance on the same order as the stabilization line 116 resistance. A slightly different field factor will result from the reduced width, but this may be calibrated one time in the product development phase.

Referring to FIG. 7, another adjustment that may be made to minimize self test resistance for an all-series wiring method is to keep the self test line 120 narrow (portion 702) while it is over the tunnel junctions 100 (the sense layer 102 and reference layer 104 are shown in the figure) for larger field factors and more concentrated field application and to flare it out to a larger width (portion 704) when passing over regions of the bridge or bridge array without active tunnel junctions 100. Finally, for the optimal chip area efficiency, an additional metal layer may be introduced that routes self test lines 120 under the sense elements 100 as well as above them in a symmetric fashion. Then, a current may pass along in one direction above the sense element 100 and in an opposing direction underneath it. This underlying interconnection may utilize a Cu or an Al process, although Cu is preferred for its improved planarity. If the area saved is a significant fraction of die that would otherwise only be occupied as a return path for the “pancake coil”, then the slightly higher cost from an additional process layer is more than compensated by the increased die count that would be available across the wafer.

Algorithms and on chip structures are described below that allow acquisition of sensor performance data through the simple introduction of additional electronic contacts and electrical current paths for generation of a magnetic field at wafer and final test. It is desirable to provide an initial offset trimming that separates any magnetic offset field that may be present from ambient fields in the final test assembly site from the intrinsic sensor electrical offset. These algorithms describe a procedure that separates the effects of an offset field from the electrical imbalance of the sensor legs. Magnetic testing and calibration can take place through purely electrical contacts and in a non-shielded environment as long as the magnetic offset fields are not time varying on a time scale similar to the measurement data rate. Once the electrical offset is known, it can either be trimmed out through blowing on chip magnetic tunnel junction anti-fuses, or a calibration factor can be stored in non-volatile memory to allow correction of the measured sensor values by the sensor ASIC; therefore, a magnetic sensor with as close to the optimal zero offset as possible is produced.

Additionally, during this process the sensitivity factors are measured and can be stored as well. Therefore, a complete sensor calibration may be achieved in the presence of a magnetic field, and utilizing only standard test apparatus present throughout the CMOS industry without any need for magnetic shielding or the application of an external magnetic field. Instead, a localized on chip test field is applied through the introduction of a current through the on-chip test coils. The method to determine the electrical offset may be done at several temperatures to accurately capture any temperature dependent offset drift and introduce compensation factors that then may be applied as the die temperature varies as measured with an on die temperature sensor. Such temperature sensors are a simple ASIC building block. Calibration for this offset temperature dependence also significantly reduces recalibration frequency required of the end user. A sensor self test mode in a final product may be used to recharacterize sensor performance in a different temperature or magnetic environment as well as calibration for effects due to aging over the life of the part, effectively increasing the sensor resolution and extending the sensor life time.

The self test metal routing alone allows for a calibration of sensitivity and a measure of functionality, but cannot provide one of the most critical sensor parameters, the offset, due to the possibility of an external interfering magnetic field. When one combines measurements at different self test currents with measurements at different stabilization current values, it becomes possible to extract the intrinsic sensor electrical offset. This is done through solving a simple system of equations:

M_{O1}=S₁(H_{O})+E_{O}

M_{O2}=S₂(H_{O})+E_{O}

where M_{O1} is the measured offset at a first stabilization current value, extracted from several measurements of the sensor with different self test currents,

S₁ is the sensor sensitivity at a first stabilization current,

H_{O} is the unknown magnetic offset,

E_{O} is the unknown electrical offset,

M_{O2} is the measured offset at a second stabilization current value, extracted from several measurements of the sensor stabilized with that current value and with different self test currents applied, and

S₂ is the sensor sensitivity at a second stabilization current.

The sensor offset is measured twice at two different levels of stabilization current, and thereby the sensitivity factors multiplying any interfering field are modulated. The electrical and magnetic offsets may thus be extracted separately, and calibration data may be written for the sensitivity and electrical offset to be used as correction factors for subsequent measurements. This may be done at final test, and testing at different temperatures may be performed to enable a correction for the temperature dependence of the offset drift as well. The final consumer product may trigger a self test mode as well to check accuracy of the calibration values or if the (previously calibrated) measured offset drift exceeds a threshold, for example due to temperature dependent effects.

During fabrication of the structure of the magnetic field sensing device 101 of FIG. 1 or after fabrication of the integrated circuit including the Wheatstone bridges 200, current may be supplied to the self test line 120 to create a magnetic field that is sensed by the magnetic tunnel devices 100. Sample magnetic field response at two or more fields generated by two or more stabilization currents through stabilization line 116 per field are used to determine sensitivity factors and electrical offset. A first stabilization current and a first self test current are applied to the magnetic field sensing device 101, with the whole system held at a first temperature, resulting in a first measurement. The stabilization current is changed to a second value while the self test is still held at the first value, for a second measurement. The self test current is then adjusted to its first value while the stabilization current is adjusted to its second value for a third measurement. Finally, the stabilization current is returned to the second value and the self test current is maintained at the second value, and a fourth measurement is taken. The sensitivity and sensor offset may then be determined for each of the two stabilization current values:

S₁=(M₁−M₃)/(ST₁−ST₂)

S₂=(M₂−M₄)/(ST₁−ST₂)

M_{O1}=½{(M₁+M₃)−S₁*(ST₁+ST₂)}

M_{O2}=½{(M₂+M₄)−S₂*(ST₁+ST₂)}

where M₁₋₄ are the measured values and ST₁ and ST₂ are the magnetic fields applied by the first and second stabilization currents.

Once M_{O1}, M_{O2}, S₁ and S₂ are determined, the formulas given above are applied and the electrical and magnetic components of the sensor offset are determined. Additional stabilization and/or self test currents may be applied to determine sensor linearity and a least squared method of determining the electrical and magnetic offset may be applied for improved accuracy and noise immunity. The procedure may be applied at more than one temperature to determine how the electrical offset changes with temperature to introduce a higher level of calibration into the system. After the calibration factors are determined, any subsequent measurement will subtract the electrical offset, and utilizing the measured slope of the electrical offset with temperature may also subtract a temperature dependent term based on this offset drift. An optional sensitivity scaling may be applied as well, based upon the temperature dependent measurements. These corrected measurement values are much more accurate than the original uncorrected values.

The capability to self test magnetic sensors by an integrated magnetic field generating line at probe, final test, and in the consumer product provides the ability to calibrate electrical offset and sensitivity of the individual sensors without application of external magnetic fields, and in the presence of a small interfering field. Any change in sensor characteristics during the life of the part can also be calibrated in the final environment. Reduced packing and test costs provide a more competitive low cost magnetic sensor.

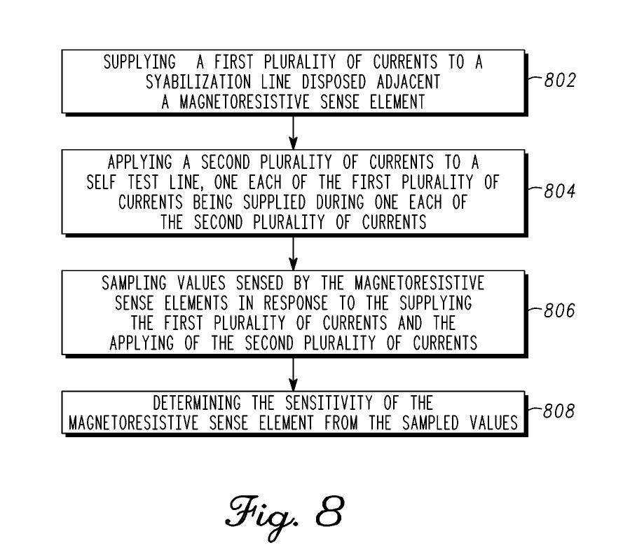

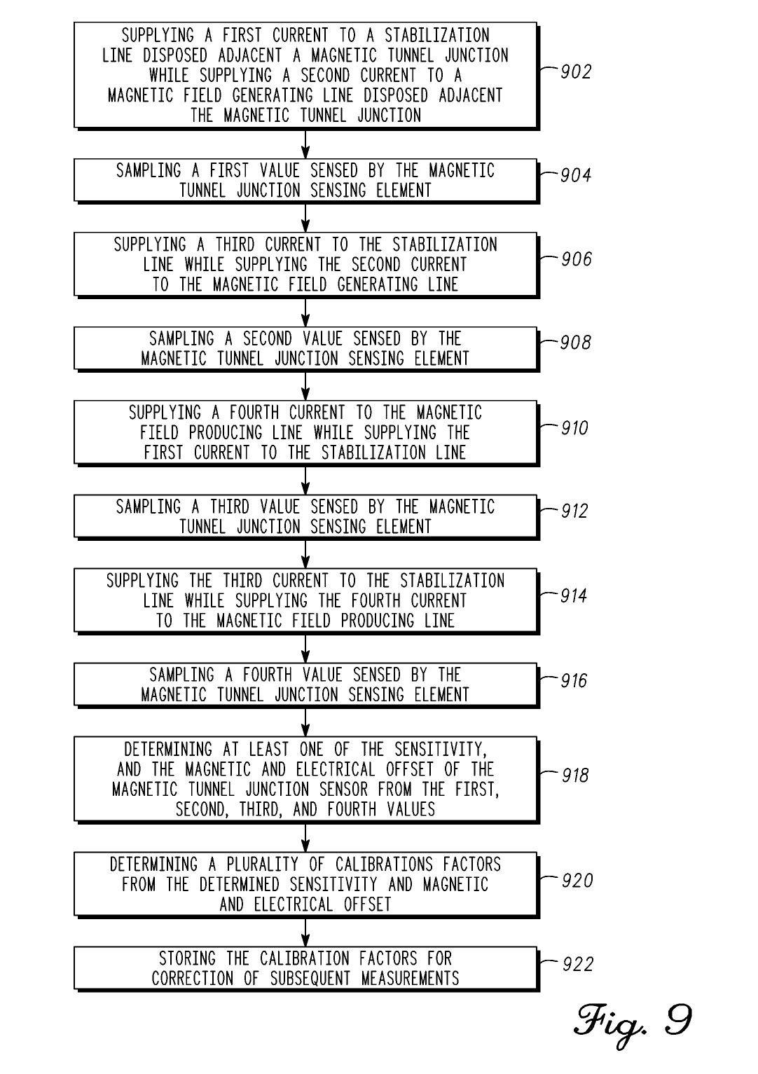

A first exemplary embodiment of a method (FIG. 8) for implementing the advantages of the magnetic tunnel junction sensor described herein, includes supplying 802 a first plurality of currents to a stabilization line 116 disposed adjacent a magnetic tunnel junction 100 and applying 804 a second plurality of currents to a self test line 116, one each of the first plurality of currents being supplied during one each of the second plurality of currents. Values sensed by the magnetic tunnel junction sensing element 101 are sampled 806 in response to the supplying of the first plurality of currents and the applying a second plurality of currents. The sensitivity of the magnetic tunnel junction sensor 101 is determined 708 from the sampled values. This determination 808 may include determining the electrical and magnetic offset, and may also include determining a temperature dependent electrical offset from which a temperature coefficient of offset is determined.

A second exemplary embodiment of a method (FIG. 9) for accomplishing the advantages of the magnetic tunnel junction sensing device 101 described herein, includes supplying 902 a first current to a stabilization line 116 disposed adjacent a magnetic tunnel junction 100 while supplying a second current to a magnetic field generating line (self test line) 120 disposed adjacent the magnetic tunnel junction 100, and sampling 904 a first value sensed by the magnetic tunnel junction sensing element 101. A third current is supplied 906 to the stabilization line 116 while supplying the second current to the magnetic field generating line 120, and a second value sensed by the magnetic tunnel junction sensing element 101 is sampled 908. A fourth current is supplied 910 to the magnetic field producing line 120 while supplying the first current to the stabilization line 116, and a third value sensed by the magnetic tunnel junction sensing element 101 is sampled 912. The fourth current is supplied 914 to the magnetic field producing line 120 while supplying the third current to the stabilization line 116, and a fourth value sensed by the magnetic tunnel junction sensing element 101 is sampled 916. A determination 918 is made of at least one of the sensitivity, and the magnetic and electrical offset of the magnetic tunnel junction sensor 101 from the first, second, third, and fourth values, and a determination 920 is made of a plurality of calibration factors from the determined sensitivity and magnetic and electrical offset. The calibration factors for correction of subsequent measurements are stored 922.

It has been shown that sensitivity factors and electrical offset of a magnetoresistive sensor 101 may be determined from sampled magnetic field response at two or more self test fields generated by two or more self test currents through a self test line 120, measured in conjunction with two or more stabilizing currents. Furthermore, this determination may be done as the temperature varies to capture any temperature dependent offset drift, providing compensation factors that may be applied as the temperature varies.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A magnetic field sensor, comprising:
first and second current carrying lines;
a stabilization line;
a first magnetoresistive sensing element positioned between the first and second current carrying lines and adjacent to the stabilization line; and
a magnetic field generating line positioned adjacent the first magnetoresistive sensing element.

2. The sensor of claim 1 wherein the magnetoresistive sensing element comprises a magnetic tunnel junction.

3. The sensor of claim 1 wherein the first magnetoresistive sensing element comprises:
an array of magnetoresistive elements.

4. The sensor of claim 1 wherein the stabilization line is disposed on opposed sides of the first magnetoresistive sensing element so that a current passing therethrough flows in opposed directions on the opposed sides.

5. The sensor of claim 1 further comprising:
second, third, and fourth magnetoresistive sensing elements configured, in conjunction with the first magnetoresistive sensing element, as a Wheatstone bridge.

6. The sensor of claim 5 wherein each of the first, second, third, and fourth magnetoresistive sensing elements comprise:
an array of magnetoresistive sense elements.

7. The sensor of claim 1 wherein the magnetic field generating line is disposed on opposed sides of the first magnetoresistive sensing element so that a current passing therethrough flows in opposed directions on the opposed sides.

8. The sensor of claim 1 further comprising:
a contact pad electrically isolated from, and comprising a same integrated circuit layer as the stabilization line; and
circuitry coupled to the contact pad.

9. The sensor of claim 1 further comprising:
a contact pad electrically isolated from, and comprising a same integrated circuit layer, as at least one of the stabilization line, the magnetic field generating line, and the first and second current carrying lines; and
circuitry coupled to the contact pad.

10. The sensor of claim 1 further comprising:
a transistor having a first current carrying electrode comprising the second current carrying line, a second current carrying electrode coupled to additional circuitry, and a control electrode coupled to control circuitry.

11. The sensor of claim 1 wherein the magnetic field generating line comprises:
a coil.

12. The sensor of claim 1 wherein the magnetic field generating line comprises:
a first portion adjacent the first magnetoresistive sensing element and having a first width; and
a second portion displaced from the first magnetoresistive sensing element and having a second width, the first width having a dimension less than the second width.

13. A method of sensing a magnetic field in an integrated circuit including at least one magnetoresistive sensing element including a ferromagnetic sense layer, the method comprising:
supplying a first current to a stabilization line disposed adjacent the magnetoresistive sense element while supplying a second current to a magnetic field generating line disposed adjacent the magnetoresistive sense element and sampling a first value sensed by the magnetoresistive sensing element;
supplying a third current to the stabilization line while supplying the second current to the magnetic field generating line and sampling a second value sensed by the magnetoresistive sensing element;
supplying the first current to the stabilization line while supplying a fourth current to the magnetic field producing line and sampling a third value sensed by the magnetoresistive sensing element;
supplying the third current to the stabilization line while supplying the fourth current to the magnetic field producing line and sampling a fourth value sensed by the magnetoresistive sensing element;
determining the sensitivity, and the magnetic and electrical offset of the magnetoresistive sensor from the first, second, third, and fourth values;
determining a plurality of calibration factors from the determined sensitivity and magnetic and electrical offset; and
storing the calibration factors for correction of subsequent measurements.

14. The method of claim 13, further comprising:
sampling the first, second, third, and fourth values at a first and a second temperature;
determining the temperature coefficient of offset utilizing the temperature dependent electrical offset; and
storing the temperature coefficient of the offset into memory to increase the calibration precision over an extended temperature range.

15. The method of claim 13 wherein the determining a plurality of calibration factors comprises utilizing the equations:
M_{O1}=S₁(H_{O})+E_{O}
M_{O2}=S₂(H_{O})+E_{O}, where
M_{O1} is the measured offset at a first stabilization current value, extracted from several measurements of the sensor with different self test currents,
S₁ is the sensor sensitivity at a first stabilization current,
H_{O} is the unknown magnetic offset,
E_{O} is the unknown electrical offset,
M_{O2} is the measured offset at a second stabilization current value, extracted from several measurements of the sensor stabilized with that current value and with different self test currents applied, and
S₂ is the sensor sensitivity at a second stabilization current.

16. A method of sensing a magnetic field in an integrated circuit including at least one magnetoresistive sensing element, the method comprising:
supplying a first plurality of currents to a stabilization line disposed adjacent the magnetoresistive sense element;
applying a second plurality of currents to a self test line, one each of the first plurality of currents being supplied during one each of the second plurality of currents;
sampling values sensed by the magnetoresistive sensing element in response to the supplying of the first plurality of currents and applying the second plurality of currents; and
determining the sensitivity of the magnetoresistive sensor from the sampled values.

17. The method of claim 16 wherein the determining step comprises:
determining the electrical and magnetic offset

18. The method of claim 16 further comprising:
performing the supplying, applying, sampling, and determining steps at a plurality of temperatures, wherein the sampling step includes determining a temperature dependent electrical offset;
determining the temperature coefficient of offset utilizing the temperature dependent electrical offset; and
storing the temperature coefficient of the offset into memory to increase the calibration precision over an extended temperature range.

19. The method of claim 16 further comprising:
performing the supplying, applying, sampling, and determining steps at a plurality of temperatures, wherein the sampling step includes determining a temperature dependent electrical offset;
determining the temperature coefficient of the sensitivity; and
storing the temperature coefficient of the sensitivity into memory to increase the calibration precision over an extended temperature range.

20. The method of claim 16 wherein the determining step comprises:
applying the equations comprising:
S₁=(M₁−M₃)/(ST₁−ST₂)
S₂=(M₂−M₄)/(ST₁−ST₂)
M_{O1}=½{(M₁+M₃)−S₁*(ST₁+ST₂)}
M_{O2}=½{(M₂±M₄)−S₂*(ST₁+ST₂)}
where M₁, M₂, M₃, and M₄ are the sampled values and ST₁ and ST₂ are the magnetic fields applied by the first plurality of currents.
